(19) United States
(12) Patent Application Publication
(10) Pub. No.: US 2020/0016634 A1
(43) Pub. Date: Jan. 16, 2020

(54) DEVICE AND METHOD FOR REMOVING A LAYER FROM A SUBSTRATE

(71) Applicant: Nathalie Seninck, Dordives (FR)

(72) Inventor: Nathalie Seninck, Dordives (FR)

(21) Appl. No.: 16/582,078

(22) Filed: Sep. 25, 2019

Related U.S. Application Data
(63) Continuation of application No. PCT/IB2018/052068, filed on Mar. 27, 2018.

(30) Foreign Application Priority Data
Mar. 29, 2017 (DE) 102017106724.8

(51) Int. Cl. B08B 7/00; H05H 1/34; H01J 37/32

(52) U.S. Cl. CPC B08B 7/0021; H05H 1/34; B08B 7/0035; H01J 2237/335; H01J 37/3244; H01J 2237/006; H01J 37/32091

(57) ABSTRACT

At least one device (1) and at least one method for removing a layer (22) from a substrate (20) by applying a pulsed high voltage are disclosed. For this purpose, at least one pressure plasma burner (2) operating at atmospheric-pressure, a high-voltage source (3), and a supply of process gas (4) are required. Via a gas line (10), the supply of process gas (4) is connected with an inlet (6) of the plasma burner (2). The plasma burner (2) has a nozzle (7) through which a plasma jet (8) emerges. The high-voltage source (3) is configured such that a pulsed high voltage is applied between the plasma burner (2) and an electrically conductive element (11), which pulsed high voltage reaches a breakdown voltage in the region (29) of the conductive element (11).

### CROSS-REFERENCE TO RELATED APPLICATIONS

The present application is filed under 35 U.S.C. §§ 111(a) and 365(c) as a continuation of International Patent Application No. PCT/IB2018/052068, filed Mar. 27, 2018, which application claims priority of German patent Application DE 10 2017 106 724.8, filed on Mar. 29, 2017, which applications are hereby incorporated by reference in their entireties.

### FIELD

The present invention relates to a device for removing a layer from a substrate. In particular, the device comprises a plasma burner operating at atmospheric pressure. For this purpose, a high-voltage source is connected to an electrode inside the plasma burner and to a housing of the plasma burner. A supply of process gas is connected via a gas line to an inlet of the plasma burner. The plasma burner has formed a nozzle through which a plasma jet emerges.

Furthermore, the invention relates to a method for removing a layer from a substrate. In particular, for this purpose, at least one plasma burner operating at atmospheric pressure is provided. A high-voltage source is connected to an electrode inside the plasma burner and to a housing of the plasma burner. A supply of process gas is connected via a gas line to an inlet of the plasma burner. A plasma jet emerges from the plasma burner via a nozzle formed in the plasma burner.

### BACKGROUND

The efficient removal of layers, for example, lacquer layers in the course of maintenance and/or corrosion protection, is an important process that is carried out with a wide range of devices and methods of the prior art.

It is known from prior art that typically thick layers (> 1/100 mm) are always first mechanically cleaned, for example by grinding, sandblasting or brushing, and then cleaned afterwards. This creates large amounts of dust and the product surface can be damaged. Another well-established method is burning with flame or hot air. Although this does not generate dust, but, according to the composition of the layer, it may create a high emission of harmful fire gases. Also wet chemical processes with aggressive pickling or etching can be dangerous in the application. Remains of the stain can later lead to component corrosion and must be completely removed after the process. Modern methods, such as laser cleaning or dry ice blasting (with CO₂), are not applicable in all cases and may be very costly. Dry ice blasting requires a continuous supply of a CO₂ blasting agent. A disadvantage of the laser method is that the removal takes place sequentially and layer by layer from the outer to the inner layer, and the removal rate strongly depends on the absorption coefficients of the materials to be removed.

U.S. Pat. No. 8,981,251 discloses an atmospheric pressure plasma source, a body having a distal end, a blade extending from the distal end and terminating at a blade edge, a plasma-generating unit, and a plasma outlet communicating with the plasma-generating unit and positioned at the distal end. The plasma outlet is oriented at a downward angle, generally toward the blade edge, the plasma outlet providing a plasma path directed generally toward the blade edge. The plasma may be applied to the coating at an interface between the coating and an underlying substrate. While applying the plasma, the blade is moved into contact with the coating at the interface, the blade assisting in separating the coating from the substrate while one or more components of the coating react with energetic species of the plasma.

German Utility Model DE 20 2006 0019 461 U1 discloses a device for removing at least one lacquer layer from a substrate surface. A plasma jet emerging from an orifice of an atmospheric plasma is directed onto the substrate surface. The plasma nozzle is housed in an electrically insulated housing which is guided manually.

### SUMMARY

An object of the present invention is to provide a device for removing a layer from a substrate, with which the layer removal can be carried out in a particularly efficient, material and environmentally friendly manner.

This object is achieved by a device for removing a layer on a substrate, comprising at least one plasma burner operating at atmospheric-pressure; a high-voltage source connected to an electrode inside the plasma burner and connected to a housing of the plasma burner; a supply of process gas connected via a gas line to an inlet of the plasma burner; a nozzle formed in the plasma burner, through which a plasma jet emerges, wherein the high-voltage source is configured such that between the plasma burner and an electrically conductive element, a pulsed high voltage is applied, which reaches a breakdown voltage in a region of the electrically conductive element.

A further object of the present invention is to provide a method for removing a layer from a substrate, with which the layer removal can be carried out in a particularly efficient, material and environmentally friendly manner. This object is achieved by a method for removing a layer from a substrate, wherein at least one plasma burner operating at atmospheric-pressure is provided; wherein a high-voltage source is connected to an electrode inside the plasma burner and to a housing of the plasma burner; wherein a supply of process gas is connected via a gas line with an inlet of the plasma burner, and wherein a plasma jet emerges via a nozzle formed by the plasma burner, the method comprising the following step: applying a pulsed high voltage between the plasma burner and an electrically conductive element so that a breakdown voltage is achieved in the region of the conductive element, wherein the pulsed high voltage is a unipolar pulse sequence having a frequency of 10 kHz to 1 MHz, and/or the high voltage has a maximum amount of the potential of 1 kV to 100 kV related to the potential of the electrically conductive element, and/or the pulsed high voltage has an edge steepness of >10⁶ V/s.

In one embodiment, the device according to the invention for removing a layer on a substrate comprises at least one plasma burner operating at atmospheric pressure. A high-voltage source is connected to an electrode inside the plasma burner and a housing of the plasma burner. A supply of process gas is connected via a gas line to an inlet of the plasma burner. In the plasma burner, a nozzle is formed, through which a plasma jet emerges. The high-voltage source is configured such that a pulsed high voltage is applied between the plasma burner and an electrically conductive element. The pulsed high voltage is dimensioned such that a breakdown voltage in the region of the conductive element is achieved.

In order to effectively remove a layer from a surface of a substrate, in principle the best point of application is the transition between the layer to be removed and the substrate. The device according to the invention has the advantage that it succeeds in “focusing” the power of the plasma burner precisely on this transition (inner surface). Here the efficiency of the process for the removal of the layer is highest. Another advantage is that it is not necessary to gradually remove the entire layer thickness of the layer to be detached. The interface becomes so stressed that the layer separates from the surface of the substrate at the interface of the layer to be removed.

The plasma burner, which operates at atmospheric pressure, in which the high-voltage source can generate a high voltage swing, according to the invention can now be operated so that an electrical breakdown occurs in an insulating or poorly conductive layer on a conductive material. As a result, high energy is released in a pulse-like manner at the transition from the insulating layer to the conductive substrate (carrier). For short pulses, a thermomechanical pressure wave is released at the interface and the layer is blasted free in a well-defined area. From an energy point of view, the potential difference across the insulating layer is highest at the time of the electrical breakdown and the swelling of the current, resulting in the highest power output. If the plasma jet (plasma flame or electric arc) is operated at a high pulse frequency and scanned over a surface of the layer, connected areas of the substrate (support) can be freed from the layer in a simple manner.

In an embodiment, the pulsed high voltage is a unipolar pulse sequence with a frequency of 10 kHz to 1 MHz. Preferably, the pulse sequence has a frequency of 100 kHz. The electrical breakdown voltage shall be reached in the layer.

In an embodiment, the high voltage has a maximum amount of the potential of 1 kV to 100 kV related to the potential of the electrically conductive element or the substrate. Preferably, a maximum amount of the high voltage of 10 kV is selected. In an embodiment, the pulsed high voltage has an edge steepness of >106 V/s.

In an embodiment, the pulsed high voltage is configured such that each pulse has a capacitively stored pulse energy of 1 mJ to 100 mJ. Preferably, the stored pulse energy may have 10 mJ.

In some embodiments, the process gas used in the device according to the invention is formed from air, nitrogen, argon, oxygen, hydrogen or a mixture of the gases listed above.

Likewise, according to a further embodiment of the invention, a supply of a solid powder is provided. The solid powder may be supplied via the gas line to the inlet of the plasma burner. According to an embodiment of the device according to the invention, the inlet of the plasma burner for feeding a process gas or the process gas with the solid powder, which ultimately impinges on the surface of the layer, is configured such that the inlet is preferably formed so that the gas flow is impressed in a circular vortex in the axis of the plasma burner.

In some embodiments, the electrically conductive element of the layer/substrate system is an electrically conductive substrate, a wedge-shaped and conductive counter electrode or an auxiliary conductive layer.

According to an embodiment of the invention, a suction means is provided between the plasma burner and the layer to be removed. With suction, it can be ensured that removal products, fragments or the emissions of the layer to be removed are transported away without contamination of the environment.

According to a further embodiment, an additional nozzle is provided for spraying a surface of the layer with an auxiliary fluid. The auxiliary fluid may be a gas, a gas with solid particles, a liquid, or a liquid with solid particles. In the event that an electrically insulating or poorly conductive layer is present on the substrate, the auxiliary fluid can be applied to the surface to be cleaned or to the layer to be cleaned. Subsequently, the removal can then be carried out with high-voltage pulses. The auxiliary fluid may consist of an aqueous fluid which wets the surface of the layer to be removed well and penetrates the porous dirt and/or oxide structures well.

In an embodiment, the electrically conductive element is, for example, configured in the form of a counter electrode. The counter electrode may be configured, for example, in the form of a blade or a scraper. Likewise, brushes may be used to mechanically remove the layer weakened by the breakdown voltage (pulsed high voltage) or the layer residues, or to mechanically assist the removal. The electrically conductive element may be formed as a conductive and wedge-shaped counter electrode in the case of a poorly conductive substrate. The counter electrode is pushed between the layer to be removed and the substrate in order to effect the electrical breakdown in the layer to be removed.

In an embodiment, the device according to the invention is configured as a hand-held device, which can be guided, also together with the optional accessories such as suction means or additional nozzle, over the layer to be removed on the substrate. According to another embodiment, a plurality of devices for removing a layer from a substrate are interconnected to form an arrangement. The individual devices or plasma burners are mechanically interconnected, so that the arrangement can be guided as a unit over the layer to be removed. With the arrangement, it is thus possible that more extensive surface areas of the layer to be removed can be processed. The arrangement of the plurality of the devices according to the invention increases the removal rate. The arrangement according to the invention may be used, for example, for the removal of oxides on metals such as rust.

In an embodiment, the electrically conductive element is a substrate which is itself electrically conductive. In particular, the resistivity may be <100 Ohm mm²/m. The substrate may lie at ground potential. The substrate may be, for example, a metal or a carbon-fiber composite material.

In an embodiment, the layer to be detached from the substrate is electrically insulating or electrically poorly conductive. In particular, the specific resistance is preferably >1000 Ohm mm²/m. The layer to be removed from the substrate may comprise plastic and/or ceramic. The layer to be removed from the substrate may be an adhered film. The layer thickness of the layer to be removed from the substrate is preferably between 10 μm and 1000 μm.

The method for removing a layer from a substrate according to the invention comprises applying a pulsed high voltage. For this purpose, at least one plasma burner operating at atmospheric pressure is provided. A high-voltage source is connected to an electrode inside the plasma burner and to a housing of the plasma burner. A supply of process gas is connected via a gas line to an inlet of the plasma burner. A plasma jet emerges via a nozzle formed in the plasma burner and impinges on a surface of the layer to be ablated. For this purpose, between the plasma burner and an electrically conductive element, which may be for example a substrate for the layer to be removed, a pulsed high voltage is applied. The pulsed high voltage achieves a breakdown voltage in the region of the conductive element. In an embodiment, the pulsed high voltage is a unipolar pulse sequence with a frequency of 10 kHz to 1 MHz. The high voltage has a maximum amount of the potential of 1 kV to 100 kV related to the potential of the electrically conductive element. In an embodiment, the pulsed high voltage has an edge steepness of >10⁶ V/s.

Due to the pulsed high voltage, an electrical breakdown occurs in the region of the conductive element, thus releasing a high energy in a pulse-like manner at the transition from the layer to the substrate. As a result, a thermo-mechanical pressure wave is released at the transition and the layer is thereby blasted free in a well-defined area.

In addition, a suction means may be provided between the plasma burner and the layer to be removed. The suction means has the advantage that the fragments or emissions of the layer released, dissolved or blasted free by the unipolar pulse sequence and/or other means are sucked off.

An auxiliary nozzle may be provided for spraying a surface of the layer with an auxiliary fluid. The auxiliary fluid may support a removal of the layer in an abrasive manner. In an embodiment, the auxiliary fluid carries away the ablation products of the layer.

To remove a layer from a substrate, a surface of the layer can be scanned in a manual or automatic manner accordingly.

The method according to the invention can be used according to one of the described embodiments, for example for the removal of oxides on metals, such as rust.

In the method according to the invention, a gas channel with increased free charge carrier density is formed between the electrode of the plasma burner and the layer/substrate system, in particular the charge carrier density can be >10⁸/cm³. Likewise, a gas channel with a dielectric strength of <1 kV/mm, typically <100 V/mm, can be formed between the electrode of the plasma burner and the substrate or layer/substrate system.

In the method according to the invention, the average thermal power transferred to the substrate is <1000 W/cm², but typically <100 W/cm², related to the area freed from the layer.

In one embodiment of the method according to the invention, a conductive auxiliary layer is applied at least to the layer to be removed.

In a further embodiment of the method according to the invention, first of all a conductive layer, followed by a predominantly electrically insulating layer, is applied to the layer to be removed.

According to the method according to the invention, an area of 0.01 mm² to 1 mm², but typically 0.1 mm², of the layer is removed per high-voltage pulse.

These and other objects, features, and advantages of the present disclosure will become readily apparent upon a review of the following detailed description of the disclosure, in view of the drawings and appended claims.

### BRIEF DESCRIPTION OF THE DRAWINGS

Various embodiments are disclosed, by way of example only, with reference to the accompanying schematic drawings in which corresponding reference symbols indicate corresponding parts, in which:

FIG. 1 shows a device for removing a layer from a substrate by using a pulsed high voltage according to an embodiment of the invention;

FIG. 2 shows another embodiment of the device according to the invention, wherein fragments of the layer to be removed are sucked;

FIG. 3 shows another embodiment of the device according to the invention, wherein in addition to gas (process gas) also solids are used, which impinge on the substrate surface;

FIG. 4 shows another embodiment of the device according to the invention, wherein a fluid is used for cooling, for supporting the removal and/or for applying an auxiliary layer;

FIG. 5A shows an initial situation of a process sequence for removing a porous layer (rust or surface contamination) from a substrate;

FIG. 5B shows a process step in which the porous layer is impregnated with fluid;

FIG. 5C shows a process step in which high-voltage pulses are applied to the layer system;

FIG. 5D shows a final situation of the process sequence in which a surface of the substrate cleaned by ablation is revealed;

FIG. 6 shows a further embodiment of the device according to the invention, wherein a conductive auxiliary layer is applied to the layer/substrate system in order to detach the layer by means of thermo-mechanical shock waves;

FIG. 7 shows an additional embodiment of the device according to the invention, wherein a blade or a wedge-shaped counter electrode is introduced and advanced to the location of removal;

FIG. 8A is a photograph of a removal of a 500 μm lacquer layer of aluminum on a test section of 32×24 mm²;

FIG. 8B is an enlarged photograph of the area marked “B” in FIG. 8A;

FIG. 9 is a photograph showing a carbon-fiber-reinforced plastic from which a 500 μm thick lacquer layer was removed without damaging the fibers; and,

FIG. 10 is a schematic view of a plurality of plasma burners connected together to treat larger areas of a substrate.

### DETAILED DESCRIPTION

At the outset, it should be appreciated that like drawing numbers on different drawing views identify identical, or functionally similar, structural elements. It is to be understood that the claims are not limited to the disclosed aspects.

Furthermore, it is understood that this disclosure is not limited to the particular methodology, materials and modifications described and as such may, of course, vary. It is also understood that the terminology used herein is for the purpose of describing particular aspects only, and is not intended to limit the scope of the claims.

Unless defined otherwise, all technical and scientific terms used herein have the same meaning as commonly understood to one of ordinary skill in the art to which this disclosure pertains. It should be understood that any methods, devices or materials similar or equivalent to those described herein can be used in the practice or testing of the example embodiments.

It should be appreciated that the term “substantially” is synonymous with terms such as “nearly,” “very nearly,” “about,” “approximately,” “around,” “bordering on,” “close to,” “essentially,” “in the neighborhood of,” “in the vicinity of,” etc., and such terms may be used interchangeably as appearing in the specification and claims. It should be appreciated that the term “proximate” is synonymous with terms such as “nearby,” “close,” “adjacent,” “neighboring,” “immediate,” “adjoining,” etc., and such terms may be used interchangeably as appearing in the specification and claims. The term “approximately” is intended to mean values within ten percent of the specified value.

The exemplary embodiments illustrated merely represent options for how a device according to the invention and a method according to the invention for removing a layer from a substrate can be configured, or the disclosed features can be combined.

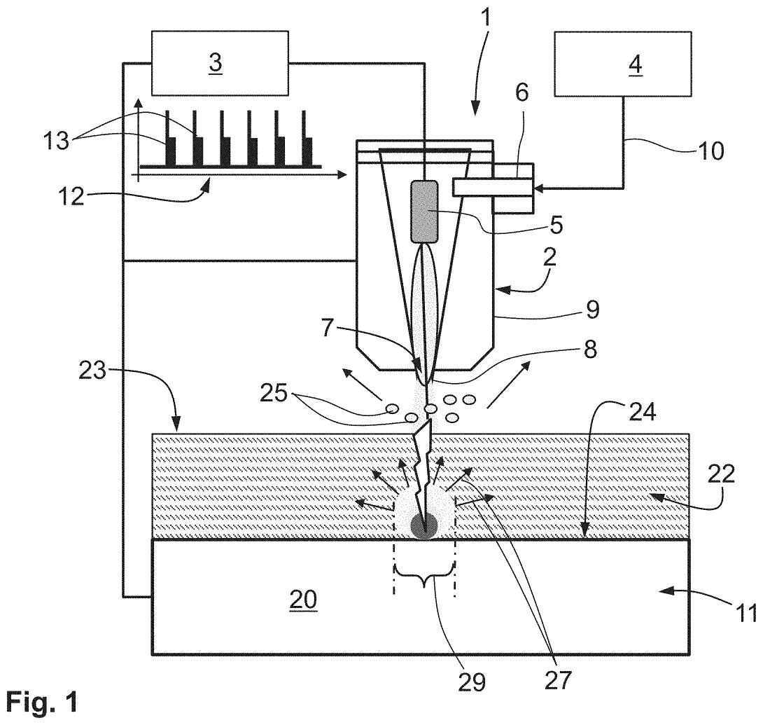

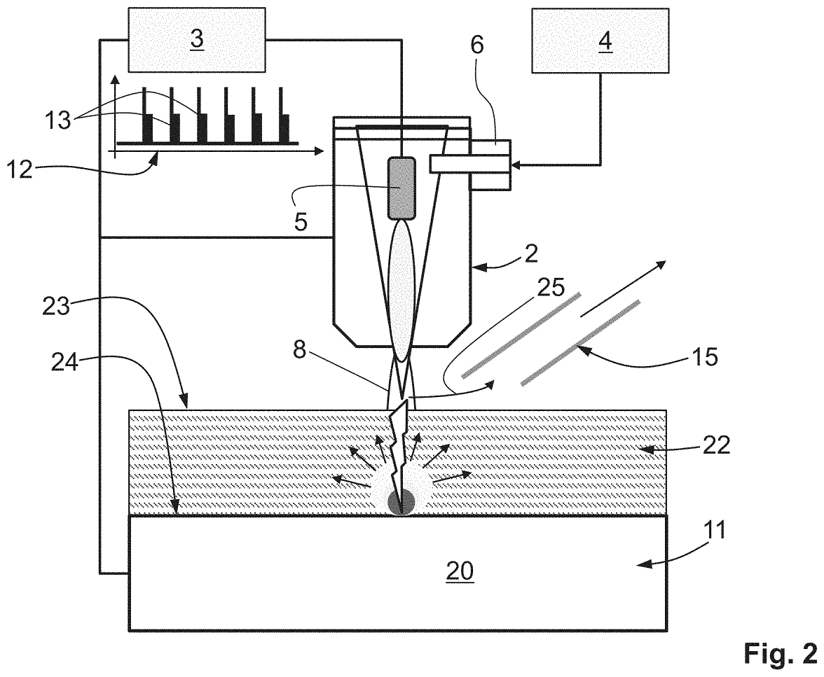

Adverting now to the figures, FIG. 1 shows an embodiment of the device 1 according to the invention for removing a layer 22 from a substrate 20. The device 1 comprises a plasma burner 2 operating at atmospheric-pressure, and the plasma burner 2 is connected to a high-voltage source 3. The high-voltage source 3 generates a unipolar pulse sequence 12 of pulses 13, which is applied to an electrode 5 in the interior of a housing 9 of the plasma burner 2. Likewise, the high-voltage source 3 is connected to the housing 9 of the plasma burner 2. A supply for process gas 4 is connected via a gas line 10 to an inlet 6 of the plasma burner 2. Thus, process gas 4 is passed into the interior of the plasma burner 2. The conductive substrate 20 (electrically conductive element 11) described in this embodiment is at ground potential. The basic structure of the device described in FIG. 1 is identical to that of FIGS. 2, 3, 4, 6 and 7 and will not be described repetitively for reasons of clarity of the description. Only the differences between the individual embodiments will be described.

The plasma burner 2 has a nozzle 7 through which a plasma jet 8 emerges and is directed onto the substrate 20 or onto the surface 23 of the layer 22 to be removed, the substrate 20 carrying the layer 22 to be removed. The high voltage applied to the electrode 5 is chosen such that, by means of the emerging plasma jet 8, a pulsed high voltage is applied to an electrically conductive element 11, which reaches a breakdown voltage in a region 29 of the conductive member 11. In the exemplary embodiment described here, the electrically conductive element 11 is the substrate 20, so that the breakdown voltage is reached at a transition 24 from the layer 22 to be removed to the substrate 20.

In the plasma burner 2 used in the device 1, the high-voltage source 3 can generate a high voltage swing. According to the invention, the high-voltage source 3 can now be operated in such a way that an electrical breakdown occurs in the insulating or poorly conducting layer 22 on the conductive substrate 20 (conductive element 11), which electrical breakdown releases energy in a pulse-like manner at the transition 24 from the insulating layer 22 to the conductive substrate 20. For short pulses, a thermo-mechanical pressure wave 27 is released at the transition 24. This causes that, in a well-defined region 29 of the layer 22, fragments 25 or emissions of the layer 22 are blasted free. From an energy point of view, at the time of the electrical breakdown and the swelling of the current, the potential difference across the insulating layer 22 is highest. This results here in the highest power output. If the plasma jet 8 (or the electric arc) is operated at a high pulse frequency and scanned over the surface 23 of the layer 22, connected areas can be freed from the layer 22 in a simple manner and thus exposed.

FIG. 2 shows another embodiment of the device 1 according to the invention. The structure of the device is essentially identical to the structure described in FIG. 1 and needs not be described in detail here. A suction means 15 is provided, with which the fragments 25 and/or emissions of the layer 22 from the well-defined region 29 can be sucked. The fragments 25 and/or emissions of the layer 22 result from the fact that the electrical breakdown is generated at the transition 24 by the plasma jet 8 impinging on the layer 22, which electrical breakdown releases energy in the manner of a pulse.

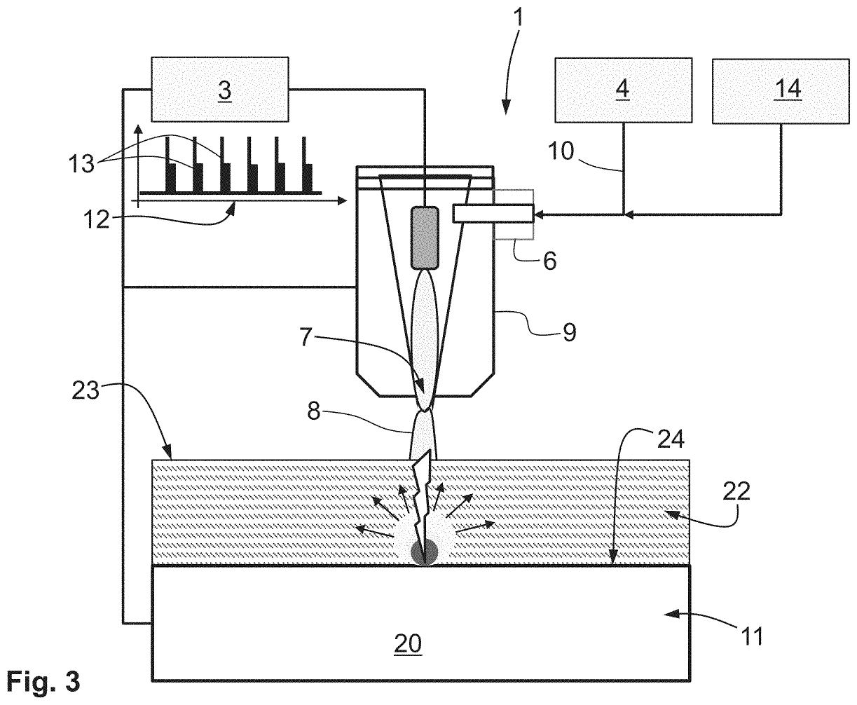

FIG. 3 shows a further embodiment of the device 1 according to the invention, wherein in addition to the process gas 4, a solid 14 can also be brought through the inlet 6 into the interior of the plasma burner 2. The mixture of process gas 4 and solid 14 reaches the surface 23 of the layer 22 via the plasma jet 8. The enriched particles of the solid 14 can serve to support the removal of the layer 22.

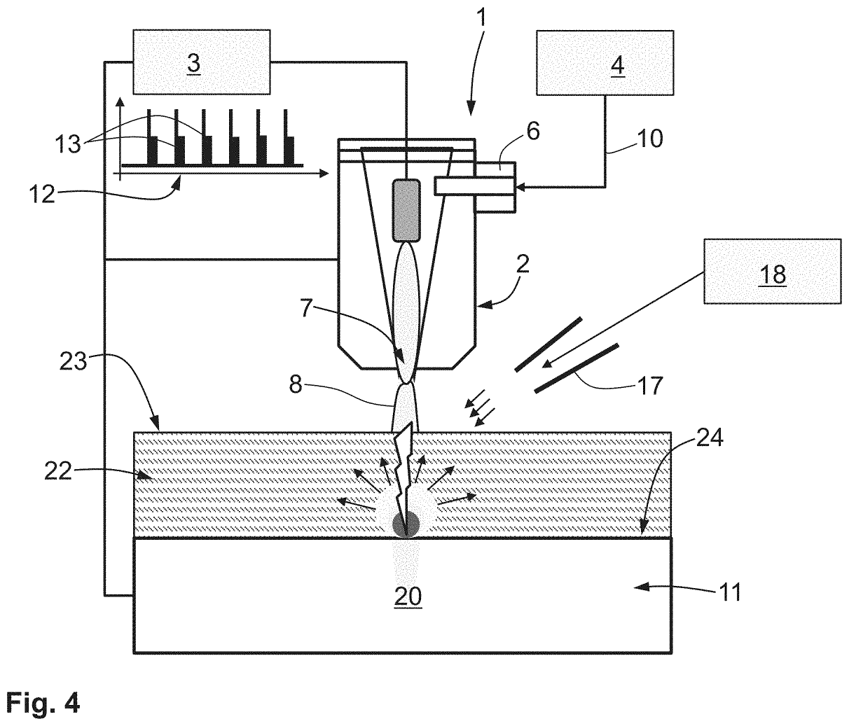

FIG. 4 shows a further embodiment of the device 1 according to the invention. The surface 23 of the layer 22 to be removed is assigned to an additional nozzle 17. Via the additional nozzle 17, an auxiliary fluid 18 can be supplied to the surface 23 of the layer 22, and also a cooling can be achieved. The auxiliary fluid 18 serves to assist in ablation, to remove dissolved fragments of the layer 22 and to apply an auxiliary layer (not shown here).

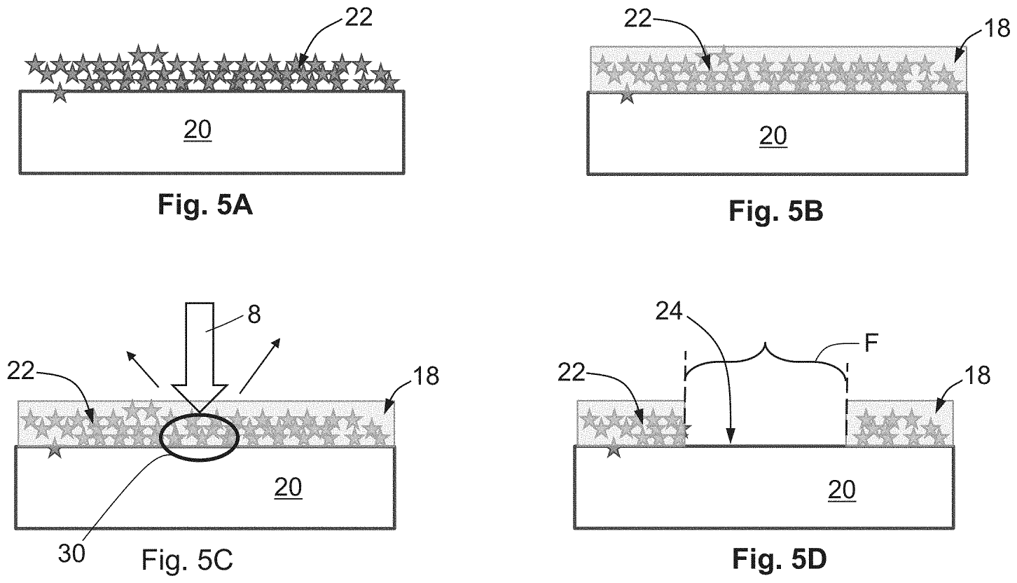

FIGS. 5A to 5D show schematically the various stages in removing a layer 22 (structure of porous corrosion and contamination) from a substrate 20. As can be seen from FIG. 5A, the layer 22 to be removed is a porous corrosion and contaminant structure which usually has dielectric properties. FIG. 5B shows the situation that the layer 22 to be detached is impregnated with an auxiliary fluid 18. The auxiliary fluid 18 wets the surface 23 well and penetrates into the electrically insulating or poorly conductive layer 22. FIG. 5C shows the situation that the plasma jet 8 is incident on the layer 22, so that an electrical breakdown 30 occurs in the region of the transition 24. The electrical breakdown 30 releases energy in a pulse-like manner at the transition 24 of the layer 22 to the conductive substrate 20. FIG. 5D shows the result of the application of the plasma jet 8 to the layer 22 of the conductive substrate 20. In a flat region F, the layer 22 is detached from the substrate 20 and the transition 24 is freely accessible.

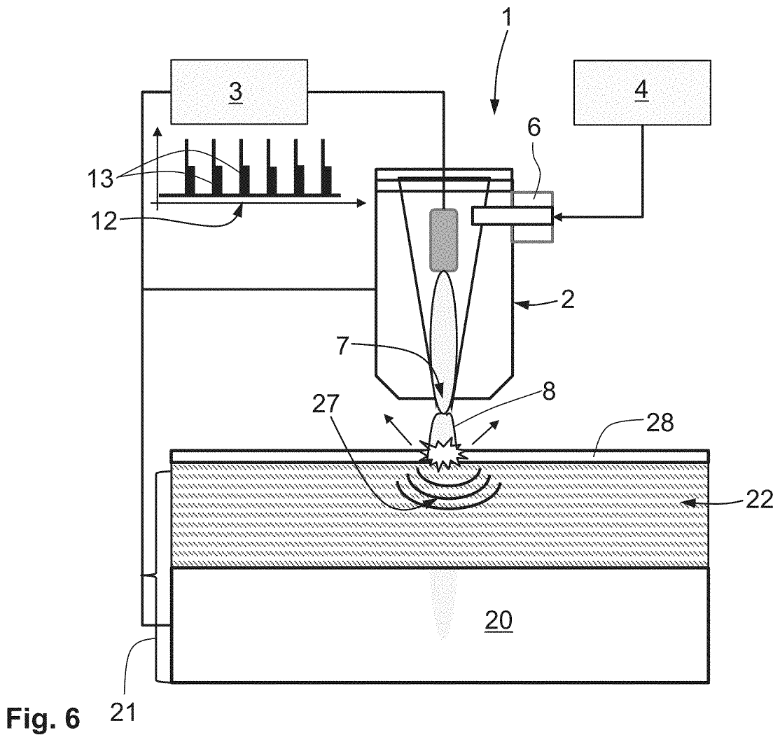

FIG. 6 shows a further embodiment of the device 1 according to the invention, wherein a conductive auxiliary layer 28 is applied to the layer/substrate system 21. The plasma jet 8 emerging from the nozzle 7 of the plasma burner 2 acts on the auxiliary layer 28. Thermomechanical shock waves 27 are thereby formed in the auxiliary layer 28 and can detach or remove the layer 22 from the substrate 20.

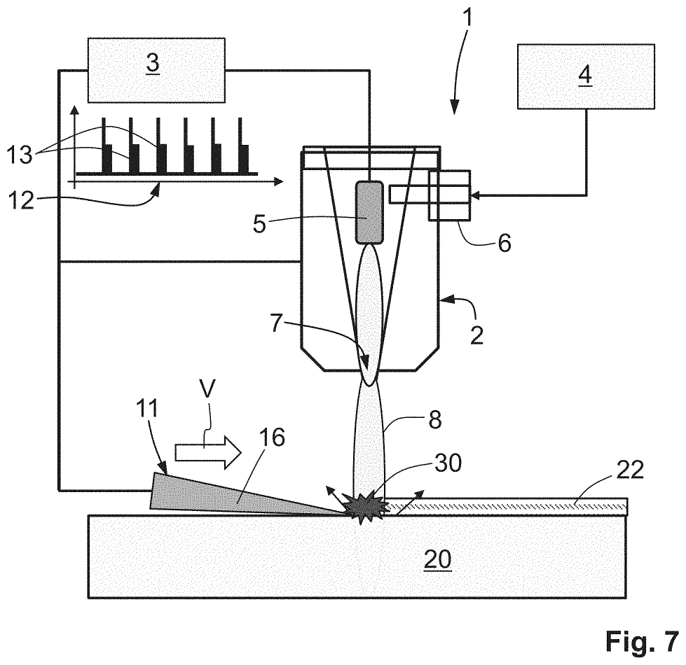

FIG. 7 shows a further embodiment of the device 1 according to the invention in which a wedge-shaped counter electrode 16 is used as the electrically conductive element 11. The wedge-shaped counter electrode 16 and the electrode 5 of the plasma burner 2 are connected to the high-voltage source 3. The conductive wedge-shaped counter electrode 16 is slid between the layer 22 to be removed and the substrate 20. The plasma jet 8 of the plasma burner is incident on the conductive and wedge-shaped counter electrode 16 and the electrical breakdown 30 is effected in the layer 22 to be detached. The counter electrode 16 or, if the substrate 20 is not conductive, the blade can be moved with a feed V to also mechanically assist in the removal of the layer 22.

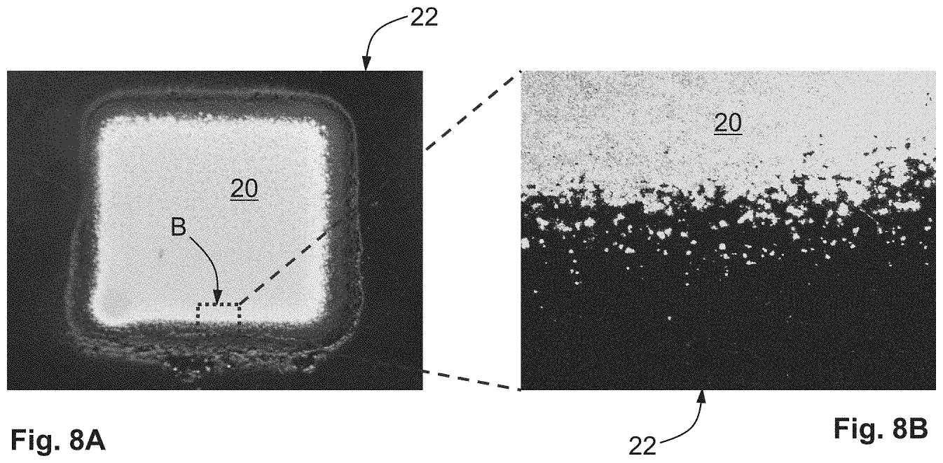

FIG. 8A shows a photograph of a removal of a 500 μm lacquer layer of aluminum (substrate) on a test section of 32×24 mm². FIG. 8B shows an enlarged photograph of the area marked “B” in FIG. 8A. It can be clearly seen from FIGS. 8A and 8B that with the device according to the invention a removal of the layer 22 from a substrate 20 is possible.

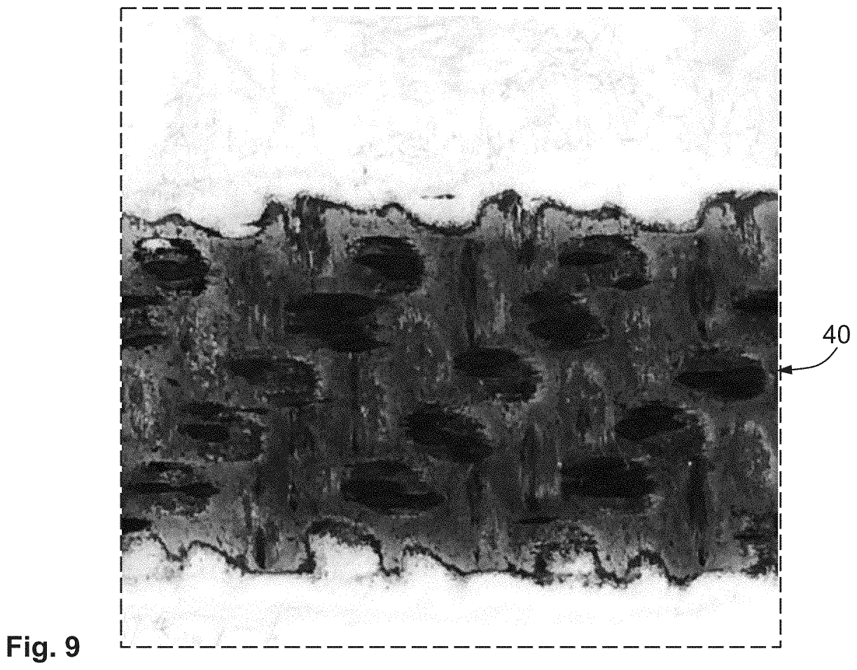

FIG. 9 shows a photograph of a carbon-fiber-reinforced plastic 40 from which a 500 μm thick lacquer layer was removed without damaging the plastic 40 or its fibers.

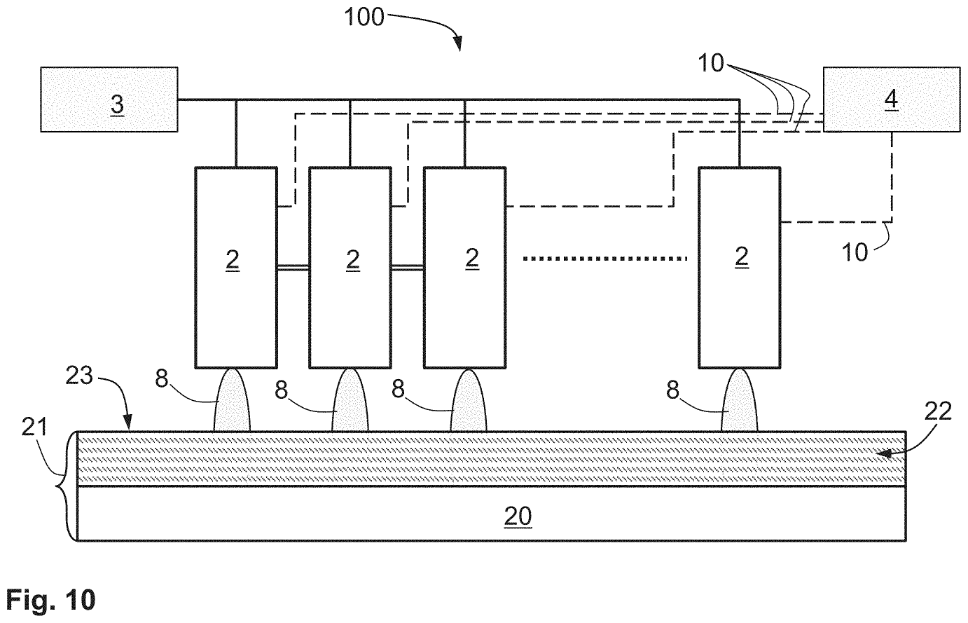

FIG. 10 shows a schematic view of an arrangement 100 with a plurality of plasma burners 2 which are connected together in order to be able to treat larger areas of a layer/substrate system 21. Each of the rigidly connected plasma burners 2 is connected to the high-voltage source 3. Likewise, each plasma burner 2, the process gas 4 can be supplied via a gas line 10. The plasma jet 8 emerging from each plasma burner 2 is incident on the layer/substrate system 21. The plurality of plasma burners 2 can be guided over the surface 23 of the layer 22 to be detached from the substrate 20.

The invention has been described in terms of preferred embodiments. It will be understood by those skilled in the art that changes and modifications of the invention may be made without departing from the scope of the following claims.

### REFERENCE NUMERALS

1 Device
2 Plasma burner
3 High-voltage source
4 Process gas
5 Electrode
6 Inlet
7 Nozzle
8 Plasma j et
9 Housing
10 Gas line
11 Electrically conductive element
12 Unipolar pulse sequence
13 Pulse
14 Solid
15 Suction means
16 Wedge-shaped counter electrode
17 Additional nozzle
18 Auxiliary fluid
20 Substrate
21 Layer/substrate system
22 Layer
23 Surface of layer
24 Transition
25 Fragment
26 Conductive counter electrode
27 Thermo-mechanical pressure wave/shock wave
28 Auxiliary layer
29 Region
30 Electrical breakdown
40 Carbon-fiber-reinforced plastic
100 Arrangement
B Area
F Flat region
V Feed

What is claimed is:

1. A device for removing a layer on a substrate, wherein the substrate is an electrically conductive substrate or an electrically conductive element, comprising:
at least one plasma burner operating at atmospheric-pressure;
a high-voltage source connected to an electrode inside the plasma burner and connected to a housing of the plasma burner;
a supply of process gas connected via a gas line to an inlet of the plasma burner;
a nozzle formed in the plasma burner, through which a plasma jet emerges,
wherein the high-voltage source is configured such that the high voltage applied at the electrode between the plasma burner and an electrically conductive element, a pulsed high voltage is applied, which reaches a breakdown voltage in a region of the electrically conductive element.

2. The device as recited in claim 1, wherein the pulsed high voltage is a unipolar pulse sequence having a frequency of 10 kHz to 1 MHz, and/or the high voltage has a maximum amount of the potential of 1 kV to 100 kV related to the potential of the electrically conductive substrate or the electrically conductive element, and/or the pulsed high voltage has an edge steepness of >10⁶ V/s.

3. The device as recited in claim 1, wherein the pulsed high voltage is configured such that each pulse has a capacitively stored pulse energy of 1 mJ to 100 mJ.

4. The device as recited in claim 1, wherein the process gas is formed from air, nitrogen, argon, oxygen, hydrogen or a mixture of the aforementioned gases.

5. The device as recited in claim 1, wherein a supply for a solid powder is provided, which is fluidly connected to the gas line.

6. The device as recited in claim 1, wherein the electrically conductive element is a wedge-shaped and conductive counter electrode or a conductive auxiliary layer.

7. The device as recited in claim 1, wherein a suction means is provided between the plasma burner and the layer to be removed.

8. The device as recited in claim 1, wherein an additional nozzle for spraying a surface of the layer is associated with an auxiliary fluid, wherein the auxiliary fluid is a gas, a solid particle gas, a liquid, or a solid particle liquid.

9. The device as recited in claim 1, wherein the device is configured as a hand-held device.

10. An arrangement comprising a plurality of interconnected devices as recited in claim 1 for removing a layer from a substrate.

11. A method for removing a layer from a substrate, wherein at least one plasma burner operating at atmospheric-pressure is provided; wherein a high-voltage source is connected to an electrode inside the plasma burner and to a housing of the plasma burner; wherein a supply of process gas is connected via a gas line with an inlet of the plasma burner, and wherein a plasma jet emerges via a nozzle formed by the plasma burner, the method comprising the following step:
applying a pulsed high voltage to an electrically conductive substrate or an electrically conductive element by means of the plasma jet emerging from the plasma burner so that a breakdown voltage is achieved in a region of the conductive element or the electrically conductive substrate,
wherein the pulsed high voltage is a unipolar pulse sequence having a frequency of 10 kHz to 1 MHz, and/or the high voltage has a maximum amount of the potential of 1 kV to 100 kV related to the potential of the electrically conductive substrate or the electrically conductive element, and/or the pulsed high voltage has an edge steepness of >10⁶ V/s.

12. The method as recited in claim 11, wherein in the region of the electrically conductive substrate or the conductive element an electrical breakdown is formed at the breakdown voltage, via which electrical breakdown a high energy is released at a transition from the layer to be removed to the electrically conductive substrate or the conductive element, whereby a thermo-mechanical pressure wave is released at the transition and the layer is thereby blasted free in a well-defined region.

13. The method as recited in claim 12, wherein a suction means is provided between the plasma burner and the layer to be removed, with which suction means the fragments released by the unipolar pulse sequence and/or other means are sucked off the layer.

14. The method as recited in claim 12, wherein an additional nozzle for spraying a surface of the layer with an auxiliary fluid is provided, wherein the auxiliary fluid supports a removal of the layer in an abrasive manner.

15. The method as recited in claim 11, wherein for removing a layer from the electrically conductive substrate a surface of the layer is scanned.
